(19) United States
(12) Patent Application Publication
(10) Pub. No.: US 2017/0256563 A1
(43) Pub. Date: Sep. 7, 2017

(54) SEMICONDUCTOR MEMORY DEVICE

(71) Applicant: Kabushiki Kaisha Toshiba, Minato-ku (JP)

(72) Inventors: Toru MATSUDA, Yokkaichi (JP); Hironobu Hamanaka, Yokkaichi (JP); Tatsuo Ishida, Kuwana (JP); Junya Fujita, Nagoya (JP); Satoshi Kakinuma, Yokkaichi (JP)

(73) Assignee: Kabushiki Kaisha Toshiba, Minato-ku (JP)

(21) Appl. No.: 15/267,756

(22) Filed: Sep. 16, 2016

Related U.S. Application Data
(60) Provisional application No. 62/302,851, filed on Mar. 3, 2016.

(51) Int. Cl. H01L 27/115; H01L 23/528

(52) U.S. Cl. CPC H01L 27/11582; H01L 23/5283; H01L 27/11556

(57) ABSTRACT

A semiconductor memory device includes electrode layers stacked on a conductive layer, and columnar bodies extending in the electrode layers in a stacked direction of the electrode layers. The electrode layers include a first electrode layer and a second electrode layer positioned between the first electrode layer and the conductive layer. The columnar bodies include a first columnar body and a second columnar body. The first columnar body includes a first semiconductor layer extending in the stacked direction through the first electrode, a semiconductor body provided between the first semiconductor layer and the conductive layer, and a first insulating layer extending along the first semiconductor layer. The second columnar body includes a second semiconductor layer extending in the stacked direction through at least the first electrode layer, and a second insulating layer extending in the stacked direction along the second semiconductor layer and extending through the second electrode layer.

### CROSS-REFERENCE TO RELATED APPLICATIONS

This application is based upon and claims the benefit of priority from U.S. Provisional Patent Application 62/302,851 filed on Mar. 3, 2016; the entire contents of which are incorporated herein by reference.

### FIELD

Embodiments are generally related to a semiconductor memory device.

### BACKGROUND

A NAND-type semiconductor memory device, which has three-dimensionally disposed memory cells, comprises a plurality of electrode layers stacked on a substrate and semiconductor channel layers extending therethrough. The memory cells are disposed along the semiconductor channel layers. In such a semiconductor device, it is possible to enlarge the storage capacity thereof, for example, by densifying the semiconductor channel layers. The densifying of the semiconductor channel layers, however, may be achieved by shrinking the size thereof, and thus, may facilitate non-uniformity. The non-uniformity of the semiconductor channel layers may induce, for example, structural defects, which serve as factors of reducing the breakdown voltages between the electrode layers and the semiconductor channel layers.

### BRIEF DESCRIPTION OF THE DRAWINGS

FIG. 1 is a perspective view schematically showing a semiconductor memory device according to a first embodiment;

FIG. 2 is a schematic cross-sectional view showing a semiconductor memory device according to the first embodiment;

FIGS. 3A to 3G are schematic cross-sectional views showing a manufacturing process of the semiconductor memory device according to the first embodiment;

FIGS. 4A and 4B are schematic cross-sectional views showing a part of a manufacturing process of a semiconductor memory device according to a second embodiment; and

FIGS. 5A and 5B are partial cross-sectional views schematically showing a semiconductor memory device according to a comparable example.

### DETAILED DESCRIPTION

According to one embodiment, a semiconductor memory device includes a plurality of electrode layers stacked on a conductive layer, and a plurality of columnar bodies extending in the electrode layers in a stacked direction of the electrode layers. The electrode layers include a first electrode layer and a second electrode layer positioned between the first electrode layer and the conductive layer. The columnar bodies include a first columnar body and a second columnar body. The first columnar body includes a first semiconductor layer extending in the stacked direction through the first electrode, a semiconductor body provided between the first semiconductor layer and the conductive layer, the semiconductor body extending through the second electrode layer, and a first insulating layer extending along the first semiconductor layer. The first insulating layer includes a charge storage portion between the first electrode layer and the first semiconductor layer. The second columnar body includes a second semiconductor layer extending in the stacked direction through at least the first electrode layer, and a second insulating layer extending in the stacked direction along the second semiconductor layer. The second insulating layer includes a first portion positioned between the first electrode layer and the second semiconductor layer, and a second portion extending through the second electrode layer.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

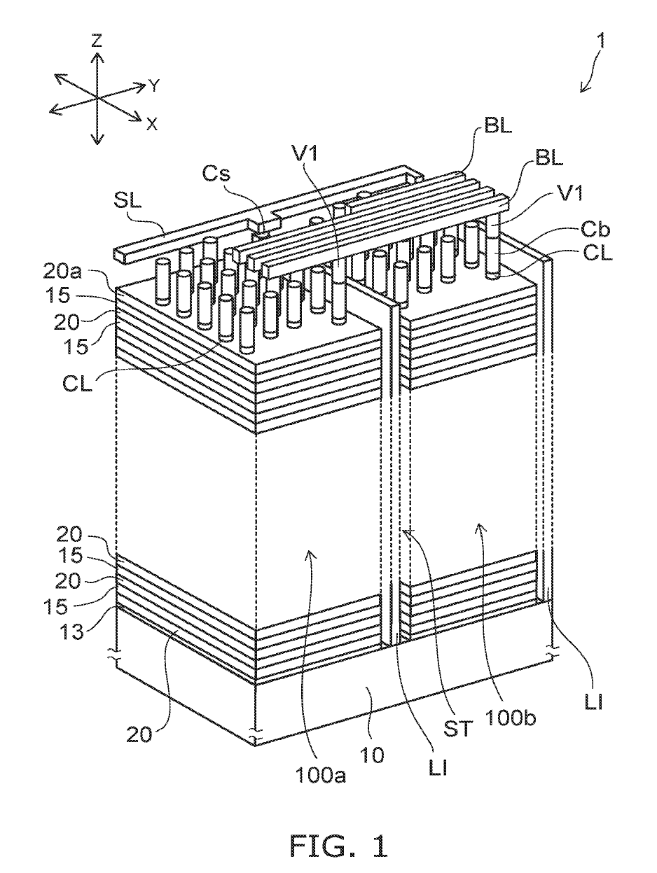

FIG. 1 is a perspective view schematically showing a semiconductor memory device 1 according to a first embodiment. The semiconductor memory device 1 includes, for example, a NAND-type non-volatile memory device having three-dimensionally disposed memory cells.

As shown in FIG. 1, the semiconductor memory device 1 includes a conductive layer (hereinafter a source layer 10), stacked bodies 100a and 100b. The stacked bodies 100a and 100b are arranged in the Y-direction on the source layer 10. The stacked bodies 100a and 100b each includes a plurality of insulating layers 15 and a plurality of electrode layers 20 stacked on the source layer 10 with an insulating layer 13 interposed. An insulating layer 15 and an electrode layer 20 are alternately disposed in a first direction (hereinafter the Z-direction), which is the stacking direction of the electrode layers 20. The insulating layer 15 electrically isolates the electrode layer 20 from other electrode layer 20 adjacent thereto in the Z-direction. The source layer 10 is, for example, a P-type well provided in a silicon substrate (not shown). Alternatively, the source layer 10 may be a poly-crystalline silicon layer provided on the silicon substrate with an interlayer insulating layer (not shown) interposed. The electrode layer 20 is, for example, a metal layer including tungsten (W). The insulating layer 15 is, for example, a silicon oxide layer.

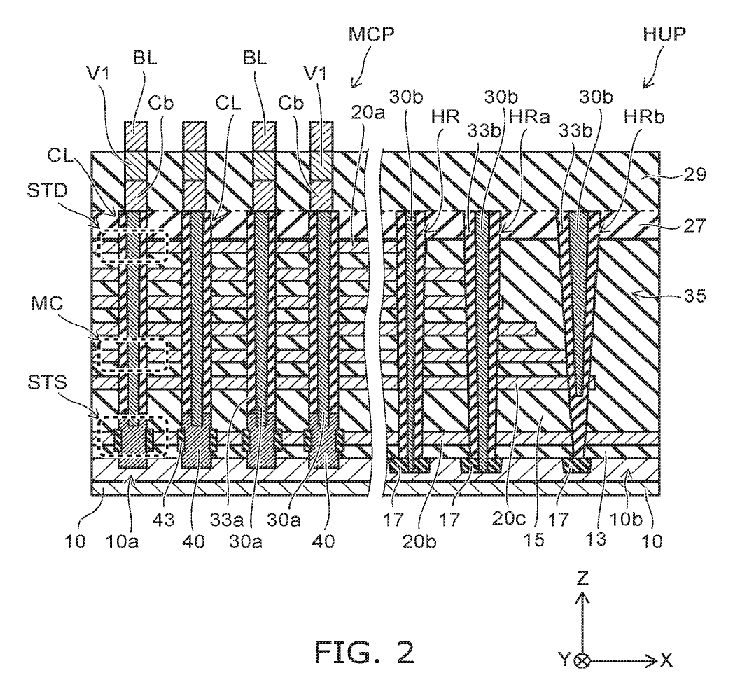

The stacked bodies 100a and 100b each include a plurality of columnar bodies CL extending in the Z-direction through the insulating layers 15 and the electrode layers 20 (see FIG. 2). The columnar bodies CL are electrically connected through contact plugs Cb and V1 respectively to bit lines BL. The bit lines BL extend, for example, in the Y-direction above the stacked bodies 100a and 100b. One of the columnar bodies CL provided in the stacked body 100a and one of the columnar bodies CL provided in the stacked body 100b share one bit line BL. It should be noted that insulating layers 27 and 29 (see FIG. 2) provided between the bit lines BL and the electrode layer 20a that is the uppermost layer of the electrode layers 20 are omitted in FIG. 1 for convenience in showing the structure of the semiconductor memory device 1.

The semiconductor memory device 1 further includes a source line SL and source contact bodies LI electrically connected to the source layer 10. A source contact body LI is provided in a slit ST between the stacked bodies 100a and 100b. The source contact body LI is, for example, a plate-shaped metal body extending in the X-direction and the Z-direction. The source contact bodies LI are electrically connected through a contact plug Cs to the source line SL. That is, the source line SL is electrically connected through the source contact bodies LI to the source layer 10. The source line SL extends, for example, in the Y-direction above the stacked bodies 100a and 100b.

FIG. 2 is a schematic cross-sectional view showing the semiconductor memory device 1 according to a first embodiment.

FIG. 2 is, for example, the schematic view showing a cross-section of the stacked body 100a taken along the X-Z plane. As shown in FIG. 2, the stacked body 100a includes, for example, a memory cell portion MCP and a hook-up portion HUP.

In the memory cell portion MCP, a plurality of columnar bodies CL are provided, which extend in the Z-direction through the electrode layers and the insulating layers. The columnar bodies CL each include a semiconductor layer 30a, an insulating layer 33a and a semiconductor body 40. In a columnar body CL, the semiconductor layer 30a extends in the Z-direction. The semiconductor body 40 is provided between the source layer 10 and the semiconductor layer 30a. Thus, the semiconductor body 40 is electrically connected to the source layer 10 and the semiconductor layer 30a respectively. The insulating layer 33a is positioned between the electrode layers 20 and the semiconductor layer 33a, and thus, extends in the Z-direction along the semiconductor layer 30a. The semiconductor layer 30a is electrically connected through the contact plugs Cb and V1 to a bit line BL.

The semiconductor body 40 is provided so as to extend through the electrode layer 20b that is the lowermost layer of the electrode layers 20. The top end of the semiconductor body 40 is positioned at a level between the electrode layer 20b and the electrode layer 20c adjacent to the electrode layer 20b in the Z-direction. The bottom end of the semiconductor body 40 is positioned, for example, at a level lower than the top surface of the source layer 10. An insulating layer 43 is provided between the electrode layer 20b and the semiconductor body 40. The insulating layer 43 is, for example, a silicon oxide. The semiconductor body 40 is not limited to the above example, but may be provided so as to extend through both the electrode layers 20b and 20c.

In the memory cell portion MCP, a selection transistor STS on a source side, memory cells MC and a selection transistor STD on a drain side are provided respectively at portions where the columnar body CL extends through the electrode layers 20. The selection transistor STS is provided, for example, at a portion where the semiconductor body 40 extends through the electrode layer 20b. The selection transistor STD is provided at a portion where the semiconductor layer 33a extends through the electrode layer 20a that is the uppermost layer. The memory cells MC are provided at portions where the semiconductor layer 33a extends through electrode layers 20 between the selection transistors STS and STD. Thus, the semiconductor memory device 1 comprises the NAND string including the memory cells MC, the selection transistors STS and STD which are disposed along the columnar body CL extending in the Z-direction.

The semiconductor body 40 acts as a channel body of the selection transistor STS. The insulating layer 43 acts as a gate insulating film of the selection transistor STS, which is provided between the electrode layer 20b and the semiconductor body 40. The electrode layer 20b acts as a selection gate of the selection transistor STS.

The semiconductor layer 30a acts as channel bodies of the memory cells MC and the selection transistor STD. The electrode layer 20a acts as a selection gate of the selection transistor STD. The electrode layers 20 positioned between the electrode layers 20a and 20b act as control gates of the memory cells MC.

The insulating layer 33a has, for example, the ONO structure where a silicon oxide, a silicon nitride and another silicon oxide are sequentially stacked in a direction from the electrode layers 20 to the semiconductor layer 30a. The insulating layer 33a acts as a charge storage portion of a memory cell MC at a portion located between the electrode layer 20 and the semiconductor layer 30a. Alternatively, the insulating layer 33a may include a conductive body that acts as a floating gate.

As shown in FIG. 2, each end portion of the electrode layers 20 are positioned in the hook-up portion HUP. The end portions of the electrode layers are disposed in a staircase, and covered with the insulating layer 35. A plurality of columnar bodies are also provided in the hook-up portion HUP. Hereinafter, a columnar body provided in the hook-up portion HUP is referred to as a columnar support body HR for distinguishing it from the columnar body CL.

The columnar support body HR extends in the Z-direction through the electrode layer 20 and the insulating layers 15. The columnar support body HR includes a semiconductor layer 30b and an insulating layer 33b. The semiconductor layer 30b extends in the Z-direction in the columnar support body HR. The insulating layer 33b is positioned between the electrode layers 20 and the semiconductor layer 30b, and extends in the Z-direction along the semiconductor layer 30b. Moreover, the top end of the semiconductor layer 30b is covered with the insulating layer 29, and electrically isolated.

As shown in FIG. 2, the columnar support bodies HR include, for example, columnar support bodies HRa and HRb. In a columnar support body HRa, a semiconductor layer 30b extends through the electrode layers 20b and 20c, wherein the electrode layer 20b is the lowermost layer of the electrode layers 20, and the electrode layer 20c is adjacent to the electrode layer 20b in the Z-direction. In contrast, a semiconductor layer 30b in a columnar support body HRb is positioned above the electrode layer 20b, and extends through the electrode layer 20c. Thus, the insulating layer 33b provided in the columnar support body HRb has a portion positioned between the electrode layer 20c and the semiconductor layer 30b and a portion extending through the electrode layer 20b.

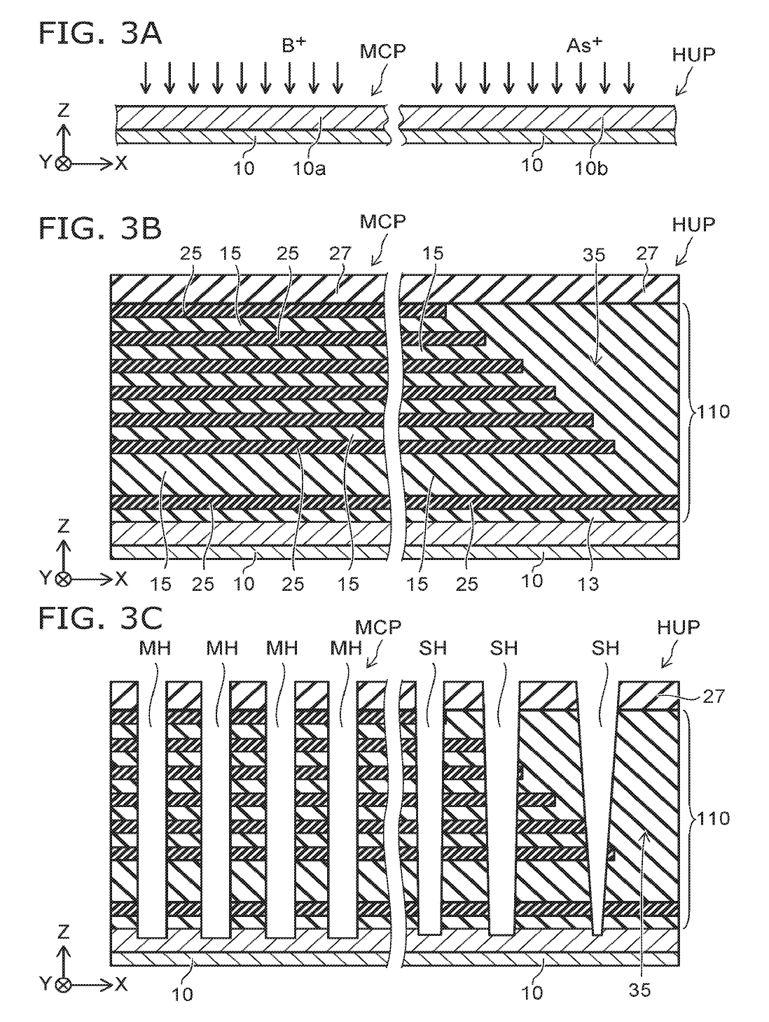

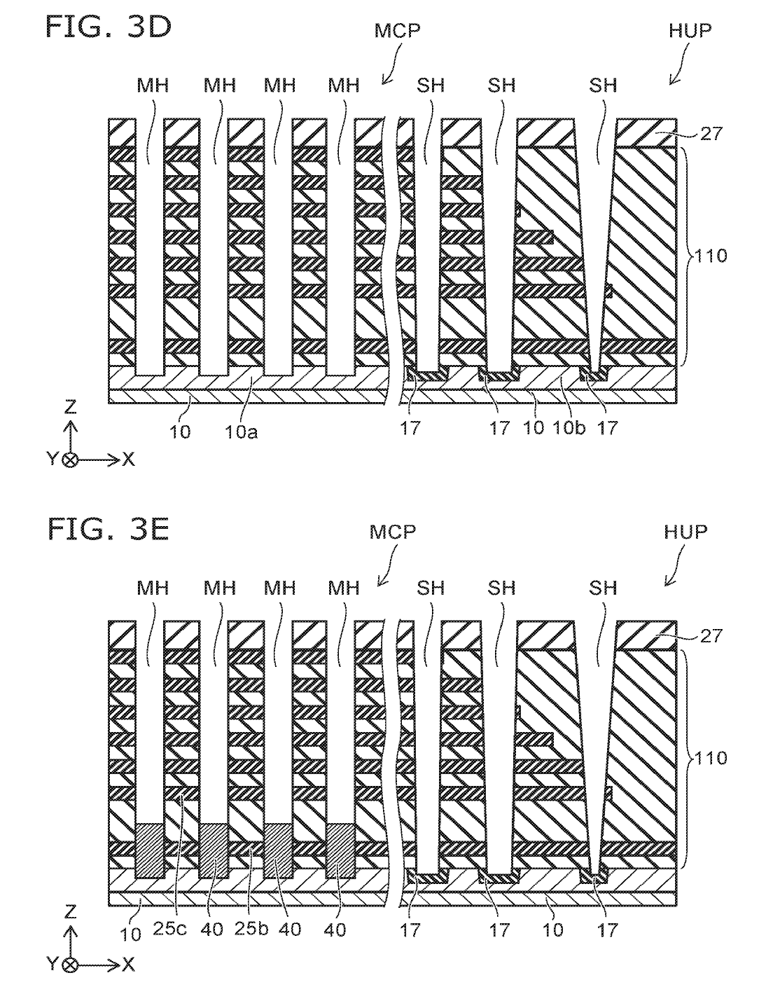

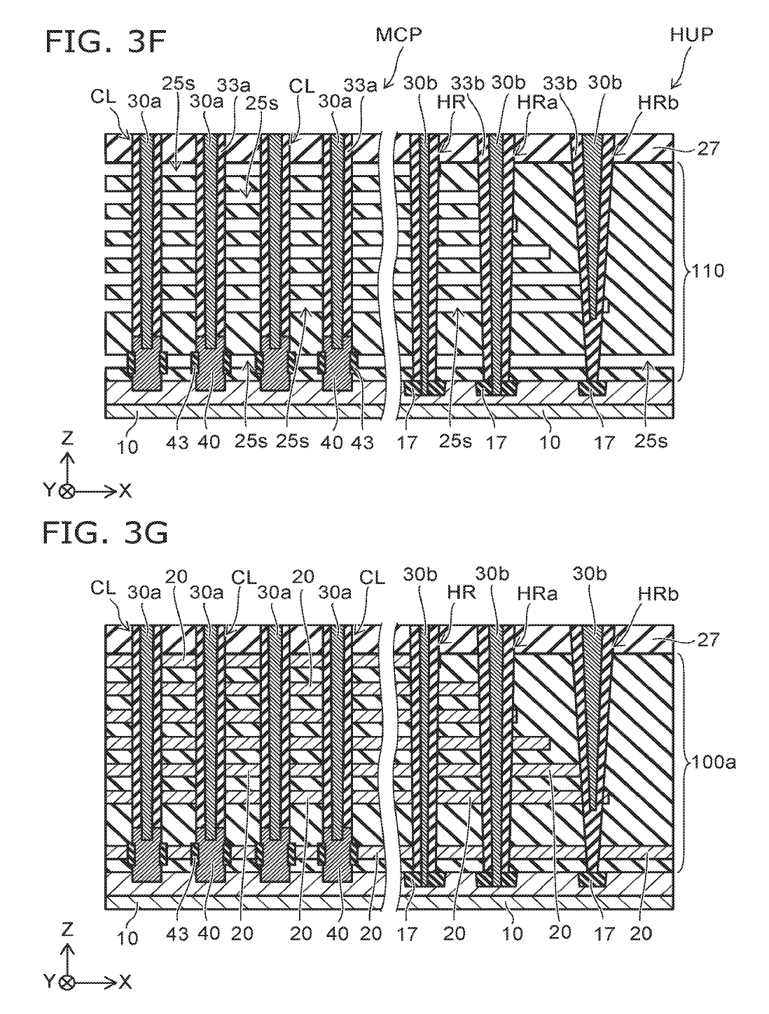

As described hereinbelow, the columnar body CL and the columnar support body HR are provided respectively in a memory hole MH and a support hole SH (see FIG. 3C) which extend in the Z-direction through the stacked body 110 provided on the source layer 10. In the memory cell portion MCP, the columnar body CL includes the semiconductor body 40 positioned between the source layer 10 and the semiconductor layer 30a. In contrast, the insulating layer 17 is provided between the columnar support body HR and the source layer 10 in the hook-up portion HUP.

The semiconductor body 40 is formed in the bottom part of the memory hole MH before the semiconductor layer 30a and the insulating layer 33a are formed in the memory hole MH. The semiconductor body 40 is, for example, a silicon layer selectively formed using epitaxial growth on the source layer 10. In the hook-up portion HUP, the epitaxial growth of silicon is prevented by the insulating layer 17 provided on the source layer 10. Accordingly, a silicon layer cannot be grown in the bottom portion of the support hole SH, and thus, a semiconductor body 40 is not provided between the source layer 10 and the semiconductor layer 30b in the columnar support body HR.

The insulating layer 17 in the hook-up portion HUP is selectively formed, for example, by thermally oxidizing the surface of the source layer 10 exposed in the bottom surface of the support hole SH before the columnar support body HR is formed. In the embodiment, the source layer 10 includes an ion-implanted layer 10b provided on the top surface side thereof. The ion-implanted layer 10b includes the impurity such as arsenic (As) that facilitates the thermal oxidization. In contrast, in the memory cell portion MCP, the source layer 10 includes an ion-implanted layer 10a provided on the top surface side thereof. The ion-implanted layer 10a includes the impurity such as boron that suppresses the thermal oxidization.

When thermally oxidizing parts of the source layer 10 exposed at the bottoms of the memory hole MH and the support hole SH respectively at the same time, an oxidized layer formed at the bottom of the support hole SH becomes thicker than another oxidized layer formed at the bottom of the memory hole MH. Thereby, it is possible to remove another oxidized layer formed at the bottom of the memory hole MH, leaving the oxidized layer formed at the bottom of the support hole SH, i.e. the insulating layer 17.

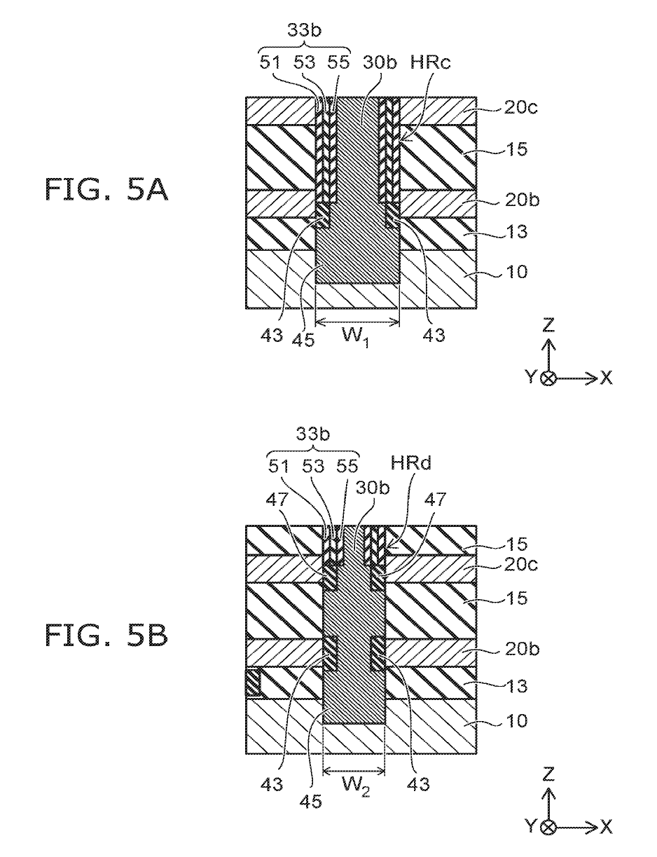

FIGS. 5A and 5B are partial cross-sectional views schematically showing columnar support bodies HRc and HRd of a semiconductor memory device according to a comparable example. A diameter W₁ of the support hole SH where the columnar support body HRc is formed is larger than a diameter W₂ of the support body SH where the columnar support body HRd is formed. In this example, the columnar support bodies HRc and HRd each include a semiconductor layer 45 between a source layer 10 and a semiconductor layer 30b. The semiconductor layer 45 is, for example, a silicon layer epitaxially grown on the source layer 10, and simultaneously formed with a semiconductor body 40 in a memory cell portion MCP (not shown). In the columnar support body HRc, an insulating layer 43 is formed between an electrode layer 20b and the semiconductor layer 45. In the columnar support body HRd, an insulating layer 47 is further formed between an electrode layer 20c and the semiconductor layer 45.

In the example shown in FIG. 5A, the insulating layer 45 is in contact with an insulating layer 33b at the same level in the Z-direction with the electrode layer 20b. A structural defect, for example, may be easily induced at an interface between the insulating layer 33b and the insulating layer 43, and thus, the breakdown voltages between the electrode layer 20b and the semiconductor layer 30b and between the electrode layer 20b and the semiconductor layer 45 may be reduced in such a structure.

In the example shown in FIG. 5B, the insulating layer 47 is in contact with the insulating layer 33b at the same level with the electrode layer 20c adjacent to the electrode layer 20b in the Z-direction. In this structure, a structural defect may also be easily induced at an interface between the insulating layer 33b and the insulating layer 43, and may reduce the breakdown voltages between the electrode layer 20c and the semiconductor layer 30b and between the electrode layer 20c and the semiconductor layer 45.

The structures shown in FIGS. 5A and 5B are formed, when the diameter W₁ of the support hole SH is larger than the diameter of the memory hole MH, and the diameter W₂ of another support hole SH is smaller than the diameter of the memory hole MH. The growth rate of the epitaxial growth in the support hole SH of the diameter W₁ is smaller than the growth rate of the epitaxial growth in the memory hole MH. On the other hand, the growth rate of the epitaxial growth in the support hole SH of the diameter W₂ is larger than the growth rate of the epitaxial growth in the memory hole MH. Thus, when the epitaxial growth is controlled such that the top end of the semiconductor body 40 is positioned between the electrode layers 20b and 20c, the top end of the semiconductor layer 45 formed in the support hole SH may be positioned in the vicinity of the electrode layer 20b or 20c, and the breakdown voltage between the semiconductor layer 30b and the electrode layer 20b or 20c may be reduced.

In contrast, the insulating layer 17 is formed on the source layer 10 at the bottom of the support hole SH in the embodiment. Thereby, the epitaxial growth on the source layer 10 is prevented, and the formation of the semiconductor layer 45 can be avoided at the bottom of the support hole SH. Accordingly, the reduction of the breakdown voltage can be prevented between the semiconductor layer 30b and the electrode layer 20b or 20c.

Hereinafter, a manufacturing process of the semiconductor memory device 1 is described with reference to FIGS. 3A to 3G. FIGS. 3A to 3G are schematic cross-sectional views showing the manufacturing process of the semiconductor memory device 1 according to the embodiment.

As shown in FIG. 3A, an ion-implanted layer 10a is formed on the top surface side of the source layer 10 in the memory cell portion MCP. The ion-implanted layer 10a includes, for example, boron (B). On the other hand, an ion-implanted layer 10b is formed on the top surface side of the source layer 10 in the hook-up portion HUP. The ion-implanted layer 10b includes, for example, arsenic (As).

Atoms implanted in the ion-implanted layer 10a and 10b are not limited to boron (B) and arsenic (As), but a combination of atoms may be selected, which makes the thermal oxidization rate in the ion-implanted layer 10a smaller than the thermal oxidization rate in the ion-implanted layer 10b. Moreover, it is possible to make the thermal oxidization rate of the source layer 10 in the memory cell portion MCP smaller than the thermal oxidization rate of the source layer 10 in the hook-up portion HUP by forming an ion-implanted layer in one of the memory cell portion MCP and the hook-up portion HUP.

As shown in FIG. 3B, a stacked body 110 is formed on the source layer 10. The stacked body 110 includes an insulating layer 13, insulating layers 15, insulating layers 25 and an insulating layer 27, in which an insulating layer 15 and an insulating layer 25 being alternately stacked. The insulating layers 13, 15 and 27 are, for example, silicon oxide layers. The insulating layer 25 is, for example, a silicon nitride layer. The insulating layers 13, 15, 25 and 27 are formed, for example, using Chemical Vapor Deposition (CVD).

In the hook-up portion HUP, the end portions of the insulating layers 25 are formed into stairs. Further, an insulating layer 35 is formed to cover the end portions of the insulating layers 25. The insulating layer 35 is formed, for example, using CVD.

As shown in FIG. 3C, memory holes MH and support holes SH are formed from the top surface of the stacked body 110 with a depth capable of reaching the source layer 10. The memory holes MH are formed in the memory cell portion MCP, and the support holes SH are formed in the hook-up portion HUP. The memory holes MH are formed, for example, by selectively removing the insulating layers 13, 15, 25 and 27 using anisotropic RIE. The support holes SH are formed, for example, by selectively removing the insulating layers 13, 15, 25, 27 and 35 using anisotropic RIE. The source layer 10 is exposed at the bottoms of the memory holes MH and the support holes SH.

As shown in FIG. 3C, the number of insulating layers 25 through which the memory holes MH extend is constant, and thus, the memory holes MH have uniform diameters. In contrast, the number of insulating layers 25 through which the support holes extend is various. Then, the diameters and shapes of the support holes SH become non-uniform, when the insulating layer 25 is different in the etching rate from the insulating layers 15 and 35.

As shown in FIG. 3D, the insulating layers 17 are formed at the bottoms of support holes SH in the hook-up portion HUP. For example, the surface of the source layer 10 is thermally oxidized through the memory holes MH and the support holes SH. The thickness of oxidized layers formed in the bottoms of the memory holes MH becomes thinner than the thickness of oxidized layers formed in the bottoms of the support holes SH due to the ion-implanted layers 10a and 10b formed on the top surface side of the source layer 10. Then, the oxidized layers are etched through the memory holes MH and the support holes SH. At this time, it is possible to remove the oxidized layers such that the insulating layers 17 remain at the bottoms of the support holes SH.

As shown in FIG. 3E, the semiconductor bodies 40 are formed in the bottoms of the memory holes MH. The semiconductor bodies 40 are, for example, silicon layers epitaxially grown on the source layer 10. The semiconductor bodies 40 have, for example, single crystalline structure. The semiconductor bodies 40 are formed such that the top ends of the semiconductor bodies 40 are positioned between insulating layers 25b and 25c, wherein the insulating layer 25b is the lowermost layer of the insulating layers 25, and the insulating layer 25c is the one adjacent to the insulating layer 25b in the Z-direction. The epitaxial growth of silicon layers is prevented in the hook-up portion HUP by the insulating layer 17 formed at the bottoms of the support holes SH. In the embodiment, position control of the top ends in the semiconductor bodies 40 becomes easy, since the diameters of the memory holes MH are uniform, and the silicon layers are not epitaxially grown in the support holes SH. That is, there is no need for controlling the positions of both the top ends of the semiconductor bodies 40 formed in the memory holes MH and the silicon layers formed in the support holes SH.

As shown in FIG. 3F, columnar bodies CL are formed in the memory holes MH, and columnar support bodies HR are formed in the support holes SH. For example, an insulating layer 33a is formed to cover an inner surface of a memory hole MH, and an insulating layer 33b is formed to cover an inner surface of a support hole SH. The insulating layers 33a and 33b have a structure, for example, in which a first layer 51, a second layer 53 and a third layer 55 are stacked in order (see FIGS. 5A and 5B). The first layer 51 and the third layer 55 are, for example, silicon oxide layers formed using CVD, and the second layer is, for example, a silicon nitride layer formed using CVD. The first layer may include high-permittivity material such as hafnium oxide.

Then, a part of the insulating layer 33a, which covers the bottom surface of the memory hole MH is removed using anisotropic dry etching, leaving a part of the insulating layer 33b which covers the wall surface of the memory hole MH. At this time, the insulating layer 17 and a part of the insulating layer 33b which covers the bottom surface of the support hole SH are also removed in some of the support holes SH. Thereby, the semiconductor body 40 is exposed at the bottom surface of the memory hole MH, and parts of the source layer 10 are exposed at the bottom surfaces in some of the support holes SH.

Further, a semiconductor layer 30a is formed in the memory hole MH, and a semiconductor layer 30b is formed in the support hole SH. The semiconductor layers 30a and 30b are, for example, poly-crystalline silicon layers formed using CVD. Columnar bodies CL are formed in the memory holes MH respectively. Columnar support bodies HRa and HRb are formed in the support holes SH respectively. In a support hole SH that has a diameter smaller in the vicinity of the bottom thereof, for example, a columnar support body HRb is formed, in which the insulating layer 33b fills the bottom portion.

In a columnar body CL, a semiconductor layer 30a is electrically connected to a semiconductor body 40. In a columnar support body HRa, a semiconductor layer 30b is electrically connected to the source layer 10. The bottom end of the semiconductor layer 30b locates, for example, at a lower level than a level of a top surface of the source layer 10 on which the insulating layer 17 is not provided. Moreover, not in every columnar support body HRa, a semiconductor layer 30b is electrically connected to the source layer 10, but there may be some columnar support bodies HRa in which a semiconductor layer 30b is not electrically connected to the source layer 10, for example, when an insulating layer 33b is formed to be thick on a bottom surface of a support hole SH.

Then, spaces 25s are formed in the stacked body 110 by selectively removing the insulating layers 25. The insulating layers 25 are removed, for example, by supplying etching liquid through slits ST (see FIG. 1) which divide the stacked body 110. When the insulating layers 25 are silicon nitride layers, the insulating layers 25 may be selectively removed, for example, using hot phosphoric acid solution. The columnar bodies CL support the insulating layers 15, and maintain the species 25s in the memory cell portion MCP. The columnar support bodies HR support the insulating layers 15, and maintain the species 25s in the hook-up portion HUP.

As shown in FIG. 3G, electrode layers 20 are formed in the spaces 25s (see FIG. 3F) formed after the insulating layers 25 are removed, then completing the stacked bodies 100a and 100b, for example. The electrode layers 20 are, for example, metal layers deposited in the spaces 25s using CVD. An electrode layer 20 includes, for example, a barrier metal layer (not shown) and a high-melting-point metal layer. The barrier metal layer is, for example, titanium nitride (TiN), and is provided between the insulating layer 15 and the high-melting-point metal layer.

Then, a plurality of bit lines BL are formed on the insulating layer 27 via an insulating layer 29 (see FIG. 2). The semiconductor layer 30a is electrically connected to one of the bit lines BL through contact plugs Cb and V1 formed in the insulating layer 29. The columnar support bodies HR are formed in order to maintain the spaces 25s, and the semiconductor layer 30b in the columnar support body HR, for example, is not connected to any one of intersections provided thereabove.

### Second Embodiment

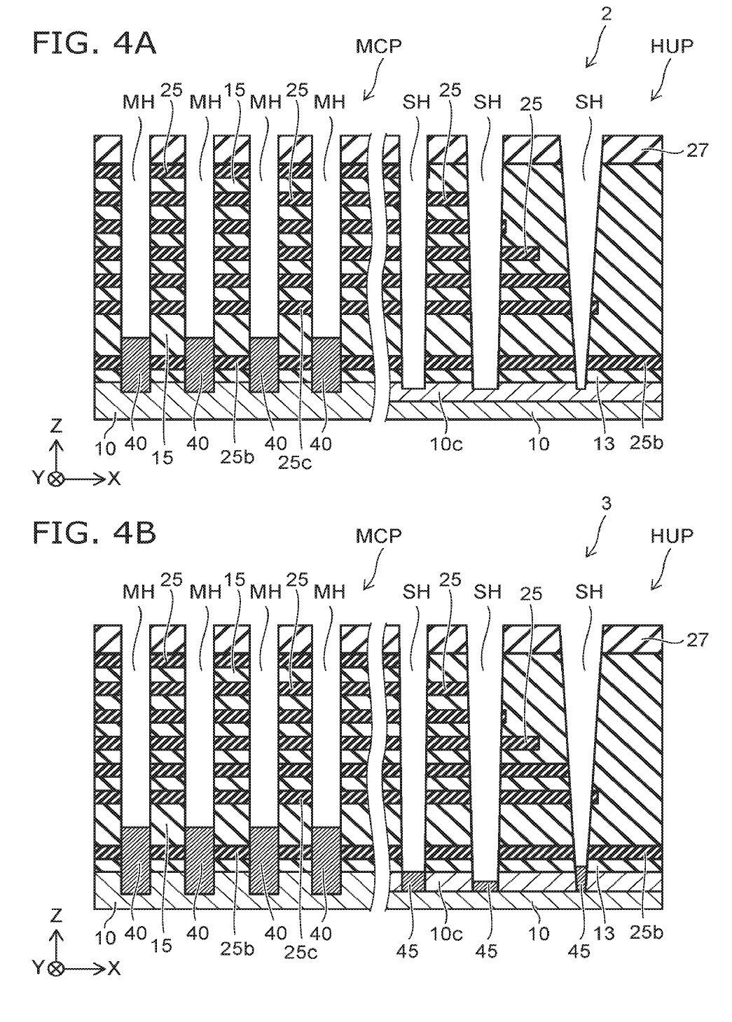

Hereinafter, semiconductor memory devices 2 and 3 according to a second embodiment are described with reference to FIGS. 4A and 4B. FIGS. 4A and 4B are schematic cross-sectional views showing a process for forming semiconductor bodies 40 in the bottoms of memory holes MH. The semiconductor memory devices 2 and 3 have a structure without providing the insulating layer 17 at the bottom of support hole SH in the hook-up portion HUP.

The semiconductor bodies 40 shown in FIG. 4A are, for example, silicon layers epitaxially grown on a source layer 10. The source layer 10 according to the embodiment includes an ion-implanted layer 10c on the top surface side thereof in the hook-up portion HUP. The ion-implanted layer 10c includes an element such as carbon (C) which suppresses the epitaxial growth.

As shown in FIG. 4A, the ion-implanted layer 10c is exposed at the bottoms of support holes SH. Then, the epitaxial growths of silicon layers, for example, are suppressed in the bottoms of the support holes SH. Thus, no silicon layer or a silicon layer having a thin thickness in the Z-direction is formed at the bottom of support hole SH.

The element forming the ion-implanted layer 10c in the hook-up portion is not limited to carbon (C), but may be, for example, nitrogen (N) or oxygen (O) and like. Nitrogen and oxygen may be bonded, for example, to a silicon atom in the ion-implanted layer 10c, and acts as a factor for inhibiting the epitaxial growth. Alternately, an inert element large in mass such as argon (Ar) may be used for suppressing the epitaxial growth by large damages formed after the ion-implantation thereof.

As shown in FIG. 4B, support holes SH may be formed in the hook-up portion HUP such that the bottoms thereof extend through the ion-implanted layer 10c. The source layer 10 is exposed at the bottoms of the support holes SH, which includes no element that forms the ion-implanted layer 10c. Accordingly, semiconductor layers 45 are formed in the bottoms of the support holes SH. The semiconductor layers 45 are silicon layers epitaxially grown, for example, at the same time as the semiconductor bodies 40.

The semiconductor layers 45 are grown on the parts of the source layer 10 exposed at the bottoms of the support holes SH. In the bottoms of the support holes SH, the ion-implanted layer 10c is exposed at the side walls thereof. Accordingly, the epitaxial growth is suppressed on the side walls. Thus, the growth rate of semiconductor layer 45 becomes smaller in the Z-direction than the growth rate of semiconductor body 40 in the Z-direction. Thereby, it is possible to control the epitaxial growth such that the top end of the semiconductor body 40 locates at a level between the insulating layer 25b and the insulating layer 25c, and the top end of the semiconductor layer 45 locates at a level lower than the insulating layer 25b, wherein the insulating layer 25b is the lowermost layer of the insulating layers 25 stacked in the Z-direction, and the insulating layer 25c is the one adjacent to the insulating layer 25b in the Z-direction.

In the embodiment, the ion-implanted layer 10c is formed in the hook-up portion HUP to suppress the epitaxial growth. Thereby, it is possible to form the semiconductor layer 45 such that the top end thereof in the support hole SH locates at a level lower than the insulating layer 25b, and to prevent the breakdown voltage from lowering between the semiconductor layer 30b and the electrode layer 20b or the electrode layer 20 locating thereabove.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a plurality of electrode layers stacked on a conductive layer; and
a plurality of columnar bodies extending in the electrode layers in a stacked direction of the electrode layers,
the electrode layers including a first electrode layer and a second electrode layer positioned between the first electrode layer and the conductive layer; and
the columnar bodies including a first columnar body and a second columnar body,
the first columnar body including:
a first semiconductor layer extending in the stacked direction through the first electrode;
a semiconductor body provided between the first semiconductor layer and the conductive layer, the semiconductor body extending through the second electrode layer; and
a first insulating layer extending along the first semiconductor layer, the first insulating layer including a charge storage portion between the first electrode layer and the first semiconductor layer, and
the second columnar body including:
a second semiconductor layer extending in the stacked direction through at least the first electrode layer; and
a second insulating layer extending in the stacked direction along the second semiconductor layer, the second insulating layer including a first portion positioned between the first electrode layer and the second semiconductor layer and a second portion extending through the second electrode layer.

2. The semiconductor memory device according to claim 1, wherein
the second columnar body extends through end portions of the first electrode layer and the second electrode layer.

3. The semiconductor memory device according to claim 1, wherein
the second semiconductor layer further extends through the second electrode layer.

4. The semiconductor memory device according to claim 3, wherein
the second semiconductor layer is electrically connected to the conductive layer.

5. The semiconductor memory device according to claim 1, wherein
the second semiconductor layer has an electrically insulated end on a side opposite to the conductive layer.

6. The semiconductor memory device according to claim 1, wherein
the first semiconductor layer has a poly-crystalline structure, and
the semiconductor body has a single-crystalline structure.

7. The semiconductor memory device according to claim 1, wherein
the second semiconductor layer includes the same material as a material of the first semiconductor layer.

8. The semiconductor memory device according to claim 1, wherein
the electrode layers each include metal.

9. The semiconductor memory device according to claim 1, further comprising:
a fourth insulating layer provided between the second semiconductor layer and the conductive layer.

10. The semiconductor memory device according to claim 9, wherein
the conductive layer includes an element suppressing a thermal oxidization thereof in a portion positioned under the semiconductor body, and another element facilitating the thermal oxidization in another portion positioned under the fourth insulating layer.

11. The semiconductor memory device according to claim 9, wherein
the conductive layer includes boron in a portion positioned under the semiconductor body, and arsenic in another portion positioned under the fourth insulating layer.

12. The semiconductor memory device according to claim 1, wherein
the conductive layer includes a first portion covering an end of the semiconductor body, and a second portion covering an end of the second insulating layer; and
the second portion includes impurities different from impurities in the first portion.

13. The semiconductor memory device according to claim 12, wherein
the second portion of the conductive layer includes an element suppressing an epitaxial growth on the conductive layer.

14. The semiconductor memory device according to claim 12, wherein
the second portion of the conductive layer includes carbon.

15. The semiconductor memory device according to claim 12, wherein
the first insulating layer has a structure in which a plurality of insulating layers are stacked, and
the second insulating layer has the same structure as the structure of the first insulating layer.
